(19) United States
(12) Patent Application Publication
(10) Pub. No.: US 2011/0036384 A1
(43) Pub. Date: Feb. 17, 2011

(54) THERMOELECTRIC DEVICE

(76) Inventor: Slade R. Culp, Coventry, CT (US)

Correspondence Address: CARLSON, GASKEY & OLDS, P.C., 400 WEST MAPLE ROAD, SUITE 350, BIRMINGHAM, MI, 48009, US

(21) Appl. No.: 12/539,683

(22) Filed: Aug. 12, 2009

(51) Int. Cl. H01L 35/34; H01L 35/30

(52) U.S. Cl. 136/201; 136/205

(57) ABSTRACT

A thermoelectric device uses two semiconductor materials, joined together. Each of the semiconductor materials is connected to a heat source, and the combined device creates a thermoelectric effect. At least one of the semiconductor materials is modified to improve the efficiency of the thermoelectric device.

### BACKGROUND OF THE INVENTION

The present application is directed toward a thermoelectric device whose thermal-electrical conversion efficiency is not limited by the efficiency of the least efficient semiconductor component.

A thermoelectric device is a device which utilizes a thermoelectric effect to perform a desired function such as creating a temperature difference, generating an electrical voltage, or measuring a temperature difference. The “thermoelectric effect” refers to a direct conversion of a temperature difference to an electric voltage, or the direct conversion of an electric voltage to a temperature difference. One example device which can be created using a thermoelectric effect is a heat pump, a device which can transfer heat from one object to another object, beyond passive heat transfer.

Thermoelectric devices, such as heat pumps, are typically created using two semiconductor materials which are joined via electrically and thermally conductive metallic joints. One of the semiconductor materials has positive charge carriers (P-type), while the other semiconductor material has negative charge carriers (N-type). The opposing charge carriers allow for an electrical voltage to buildup across the materials as heat is transferred over the materials, and therefore creates power generation via the thermoelectric effect.

When a current is applied, the heat transfer rate depends on the specific semiconductor material and differs for the N-type and the P-type materials used. Consequently, utilization of identical shaped blocks but different materials for a P-type material component and an N-type material component will result in one component's heat transfer rate being necessarily reduced to the heat transfer rate of the less efficient material.

Various techniques are used to compensate for the above described loss in heat transfer efficiency. One primary method used is to utilize a different shape between the materials. This allows a designer to design a shape which brings the heat transfer rates of the materials closer together. However, system constraints such as size and lack of interoperability can restrict a designer from realizing identical heat transfer rates in both materials using only geometrical solutions.

### SUMMARY OF THE INVENTION

Disclosed is a thermoelectric device which uses two semiconductor materials connected via a joint to create a thermoelectric effect. The thermoelectric device has connectors for connecting the device to external heat sources. At least one of the semiconductor materials is modified to allow both semiconductor materials to operate near peak efficiency.

These and other features of the present invention can be best understood from the following specification and drawings, the following of which is a brief description.

### BRIEF DESCRIPTION OF THE DRAWINGS

FIG. 1 schematically illustrates a prior art example component for creating a thermoelectric effect.

FIG. 2 schematically illustrates an example thermoelectric component utilizing multiple current loops.

FIG. 3 schematically illustrates a first example thermoelectric component connected to multiple isolated heat sources.

FIG. 4 schematically illustrates a second example thermoelectric component connected to multiple isolated heat sources.

### DETAILED DESCRIPTION OF THE PREFERRED EMBODIMENT

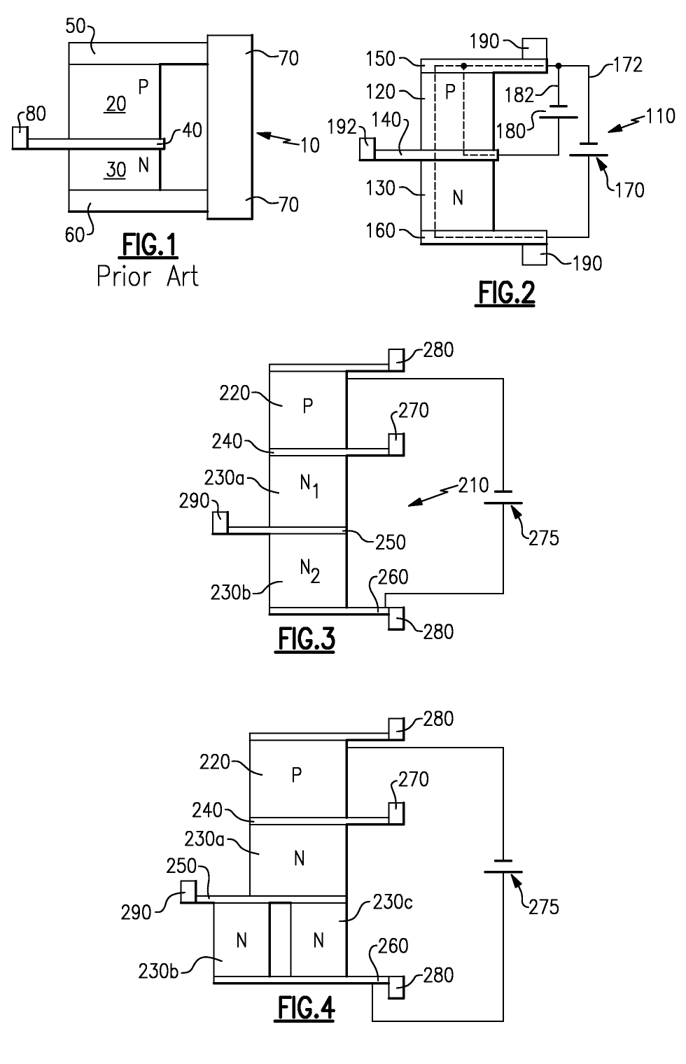

FIG. 1 illustrates a known heat pump 10 which is capable of facilitating heat transfer by creating a thermoelectric effect. The heat pump 10 has a semiconductor material block 20 with positive charge carriers (P-type) and a semiconductor material block 30 with negative charge carriers (N-type) connected by a thermal connector 40. Additionally connected to the P-type material block 20 is a thermal connector 50. The thermal connector 50 is connected to an isolated heat source 70 and allows heat transfer from the heat source 70 to the P-type material block 20 or from the P-type material block 20 to the heat source 70. A second thermal connector 60 is connected to the N-type material block 30 allowing supplemental heat transfer to or from the heat source 70. A third thermal connector 40 is connected to another isolated heat source 80. Heat flows from (to) the heat source 70 through the thermal connector 50 and material block 20 in parallel with flow through the second thermal connector 60 and the other material block 30 then through the third thermal connector 40 to (from) another isolated heat source 80. The example configuration of FIG. 1 allows heat to be drawn from the first heat source 70 into the second heat source 80 or vice-versa, depending on configuration.

In order to realize the thermoelectric effect needed to draw heat from one of the isolated heat sources 70, 80 to the other isolated heat source 80, 70, each of the P-type and N-type material blocks 20, 30 are different material types. The materials used to construct the material blocks 20, 30 are semiconductor materials with opposing type (N or P) charge carriers, and are joined by the joint 40. The joint 40 is a metallic interconnect which is capable of efficiently conducting heat as well as electricity. Each of the connectors 50, 60 are additionally constructed out of an efficient thermal and electrical conductor, and can be the same material as the joint 40 or any other suitable material. While the schematic illustration of FIG. 1 shows solid heat sources 70, 80, it is known that a heat source may be any form of heat source, including air driven by a fan, and is not limited to a solid heat source. The heat sources 70, 80 are electrically insulating to eliminate electrical short circuits within the thermoelectric device.

If no electrical current is provided to the heat pump 10, and each of the isolated heat sources 70, 80 are different temperatures, heat will flow from the hotter of the two isolated heat sources 70, 80 to the cooler of the two isolated heat sources 80, 70. For example, if the thermal connectors 50 and 60 are connected to a relatively hot heat source 70 and the other thermal connector 40 is connected to a relatively cool heat source 80, heat transfers from the hot heat source 70 to the cool heat source 80 through the P-type and N-type material blocks 20, 30, resulting in a heating/cooling action. As heat is transferred across the heat pump 10, an electrostatic voltage builds up within the heat pump 10. The effect that heat transfer has on voltage buildup (and vice-versa) is the thermoelectric effect, and has a known and predictable relationship.

The magnitude of the electrostatic voltage can be used to determine the temperature difference between the isolated heat sources. The temperature difference can be determined by measuring the magnitude of the electrostatic voltage which has built up across the heat pump 10, and then converting that voltage using the known relationship into a corresponding temperature magnitude. The conversion can be done using any standard digital controller or microcontroller.

Alternately the electrostatic voltage created by the heat transfer process could be used to provide electrical power to a system by electrically connecting the first connector 50 and the second connector 60 to the electrical system. In such a configuration the heat pump 10 would act as a voltage source providing power to the system.

It is additionally known that producing a voltage across the material blocks 20, 30 will create a heat transfer effect in the same manner that a heat transfer across the material blocks 20, 30 creates a voltage. This applied voltage allows a structure as described above to actively move heat energy from one heat source to another, and can thereby create a heating or cooling affect. As this method requires the active manipulation of the voltage, a device using this principle will not function as a generator or sensor. This known effect allows the heat pump 10 to be utilized to actively move heat from the first isolated heat source 70 to the second isolated heat source 80 by providing the heat pump 10 with an electrical current, and thereby creating a voltage across the heat pump 10. In this way, current can be used to actively cool the first isolated heat source 70, or actively heat the second isolated heat source 80, by moving heat from the first heat source 70 to the second heat source 80, or if the current is reversed 70 will heat and 80 will cool.

While the prior art heat pump 10 of FIG. 1 provides an adequate heat transfer rate across both the material blocks 20, 30 for some applications, other applications require a heat transfer rate near peak efficiency in both the material blocks 20, 30. FIG. 2 illustrates an example of a thermoelectric heat pump 110 which utilizes a supplemental electric current to increase or decrease the heat transfer efficiency of one of the material blocks, thereby moving the heat transfer rates closer together and allowing for greater heat transfer efficiency.

The example of FIG. 2 has a P-type material block 120 connected to an N-type material block 130 via a joint 140. A thermal connector 150 is connected to the P-type material block 120 as well as a first isolated heat source 190, and a similar thermal connecter 160 is connected to the N-type material block 130 as well as to the first isolated heat source 190. Both material blocks 120, 130 are additionally connected to a second isolated heat source 192 via a joint 140. An applied electrostatic voltage is represented in FIG. 2 as a voltage source 170, and causes a current loop 172 through both the P-type and the N-type material blocks 20, 30. As described above, the applied voltage 170 and resulting current 172 induces a thermoelectric heat transfer effect resulting in a temperature difference between the isolated heat sources 190, 192.

Since the P-type material block 120, and the N-type material block 130 are different materials, they require a different peak electrical current in order to obtain their most efficient heat transfer rate. Under standard thermoelectric systems one or both of the material blocks 120, with the higher peak operating current, and 130, having a lower peak operating current, will operate below its peak efficiency, due to the limitation that the currents in both materials are equivalent. In order to compensate for the varying peak operating currents the semiconductor material block 120 is modified, such as by providing a supplemental current is provided through current loop 182.

A voltage source 180 is used to create a current which runs through the supplemental current loop 182. The supplemental current loop 182 allows both semiconductor material blocks 120, 130 to operate nearer their peak current. This improves the efficiency of the semiconductor block 120 connected to the supplemental current loop 182 while simultaneously not impacting the efficiency of the other semiconductor material block 130 which is set using voltage source 170 to operate near peak efficiency. Therefore both the P-type material block 120 and the N-type material block 130 operate near their respective peak efficiencies, and the overall efficiency of the heat pump 110 is increased.

While the example of FIG. 2 utilizes a supplemental current loop through the P-type material block 120, it is understood that the supplemental current loop could also be used in the N-type material block 130 instead of the P-type material block 120. The material block 120, 130 provided with a supplemental current, as well as the magnitude of the desired supplemental current, depend on design constraints and can be determined using methods known in the art.

An alternate method of modifying one of the semiconductor material blocks to compensate for the heat transfer rate differences between the materials is illustrated in FIG. 3. In FIG. 3, the P-type material block 220 is a single block and is joined to N-type material sub-block 230a via a thermoelectric joint 240. The N-type material block 230a, 230b is split into two separate N-Type material sub-blocks 230a, 230b with an intermediate thermoelectric joint 250. One of the N-type material sub-blocks 230b is connected to another thermoelectric joint 260. Each of the thermoelectric joints 240, 250, 260 can be connected to different isolated heat sources 270, 290, 280. Also illustrated in FIG. 3 is a voltage source 275. The voltage source 275 illustrated could be either the voltage provided by a thermoelectric generation of power as the result of heat transfer over the device, or a physical voltage source connected to the device which is utilized to operate the thermoelectric device in a heat pump mode. The thermoelectric device is capable of operating in either mode, but not both modes simultaneously. When a temperature difference is applied to the heat sources 270, 280, 290 from an external source, a current will be generated. However, when a current is applied at the voltage source 275 from an external source, a heat difference between the two heat sources is generated.

In the configuration illustrated in FIG. 3, the N-type material blocks 230a, 230b are constructed of a semiconductor material which has a lower maximum temperature drop than the P-type material block 220. The maximum temperature drop relates to a maximum magnitude of heat that can be transferred out of the material in a single stage. As a result of the maximum temperature drop, the N-type material cannot efficiently transfer heat above a certain magnitude. By including the intermediary thermoelectric joint 250, and connecting it to a third isolated heat source 290, a portion of the heat is removed from the N-type material sub-block 230a before reaching the other N-type material sub-block 230b. The maximum temperature drop of the N-type material block 230a, 230b can be effectively doubled by removing the heat in two stages. This allows the N-type material sub-blocks 230a, 230b to generate a greater temperature drop than would be realized with a single thermoelectric connection 260 to an isolated heat source and could be tuned to match the maximum temperature drop of 220. Additional stages at which heat is removed could be added to further improve the efficiency, and the number of stages which can be utilized is only limited by space and weight concerns. The physical size and shapes of the blocks 220, 230 and stages can be designed according to known principles to further supplement or enhance the heat transfer efficiency.

The example of FIG. 4 illustrates another thermoelectric configuration which utilizes the effect described above with regard to FIG. 3 to remove heat from the N-type material blocks in stages. The example of FIG. 4 functions similarly to the example of FIG. 3 described above. FIG. 4 includes a third N-type material sub-block 230c placed parallel to the second N-type material sub-block 230b. By adding the third N-type material sub-block 230c thermally parallel to the second sub-clock 230b, the efficiency is further increased. The increase in efficiency is realized because the inclusion of the third N-type material sub-block 230c allows the heat transferred during the last stage of operation to be split evenly between both the N-type material sub-block 230b and the N-type material sub-block 230c, thereby effectively reducing the amount of heat transferred over each block, and increasing the effective maximum temperature drop of the N-type material block 230a, 230b, 230c.

It is understood that the examples of FIGS. 3 and 4 could be reversed with the P-type material block 220 having multiple stages and sub-blocks in the event that the P-type material is the less efficient material. Adapting the examples of FIGS. 3 and 4 to incorporate such an event would be within the skill of a person ordinarily skilled in the art. Furthermore, it is understood that the example of FIG. 2 could be used in conjunction with either the example of FIG. 3 or the example of FIG. 4 without significant modification to realize an even greater efficiency increase.

While the above examples of FIGS. 1, 2, 3 and 4 have illustrated the system with regards to a heat pump, it is known that similar systems can realize the same efficiency gains for any thermoelectric device and still fall within the above disclosure.

Although multiple embodiments of this invention have been disclosed, a worker of ordinary skill in this art would recognize that certain modifications would come within the scope of this invention. For that reason, the following claims should be studied to determine the true scope and content of this invention.

What is claimed is:

1. A thermoelectric device comprising;
a first semiconductor material block;
a second semiconductor material block connected to said first semiconductor material block via a first joint such that a thermoelectric effect is realized;
a first thermally conductive connector for connecting said first semiconductor material block to a thermal source;
a second thermally conductive connector for connecting said second semiconductor block to a thermal source; and
a modification to at least one of said material blocks such that each of said semiconductor material blocks simultaneously operate at improved efficiency.

2. The thermoelectric device of claim 1, wherein said modification includes a first set of electrical connections creating a first current loop wherein current traverses said first material block, said second material block and said first and second joint, and a second set of electrical connections creating a supplemental current loop wherein current traverses said first material block, said first joint, and said second joint.

3. The thermoelectric device of claim 2, additionally comprising a supplemental voltage source connected to said supplemental current loop.

4. The thermoelectric device of claim 3, wherein said supplemental voltage source produces an electrical current such that a heat transfer rate of said first material block is increased via the thermoelectric effect.

5. The thermoelectric device of claim 3, wherein each of said material blocks has a different peak operating current.

6. The thermoelectric device of claim 5, wherein said first material block has a greater peak operating current than said second material block.

7. The thermoelectric device of claim 6, wherein said supplemental current loop provides a magnitude of current such that the sum of the supplemental current loop and the first current loop is the peak operating current of the first material block.

8. The thermoelectric device of claim 1, wherein said modification comprises a modified second material block, said modified second material block comprising a set of at least two material sub-blocks, a first sub-block of the at least two material sub-blocks connected to said first material block via said second joint such that a thermoelectric effect is realized, a second sub-block of said set of at least two material sub-blocks is connected to said first sub-block of said at least two material sub-blocks via a third joint such that a thermoelectric effect is realized, and a third thermally conductive connector is connected to said third joint.

9. The thermoelectric device of claim 8, wherein said at least one second material block comprises a material having a lower maximum temperature drop than said first material block.

10. The thermoelectric device of claim 9, additionally comprising a third sub-block connected to said second joint and said third join thermally parallel to said second sub-block.

11. A method for increasing the efficiency of a thermoelectric device comprising the steps of:
transmitting a primary current across said thermoelectric device, wherein the magnitude of current is equal to a current at which a first portion of the thermoelectric device operates near peak efficiency, thereby forcing heat transfer across the thermoelectric device; and
transmitting a supplemental current across a second portion of the thermoelectric device, wherein the second portion of the thermoelectric device has a higher peak efficiency current than the first portion of the thermoelectric device.

12. The method of claim 11, comprising the additional step of balancing said primary current and said supplemental current such that the total current across said second portion of the thermoelectric device is equal to a current at which said second portion of the thermoelectric device operates near peak efficiency.

13. A method for increasing the efficiency of a thermoelectric device comprising the steps of;
removing heat from a first material having a higher maximum temperature drop than a second material in a single stage; and
removing heat from said second material in a plurality of stages thereby increasing an effective maximum temperature drop of said second material.

14. The method of claim 13, wherein said step of removing heat from a second material in a plurality of stages comprises a number of stages sufficient to raise an effective total maximum temperature drop of said second material to be greater than or equal to an effective maximum temperature drop of said first material.
